(19) United States
(12) Patent Application Publication
(10) Pub. No.: US 2007/0029668 A1
(43) Pub. Date: Feb. 8, 2007

(54) Package module having a stacking platform

(75) Inventors: Sem-Wei Lin, Kaohsiung (TW); Wei-Yueh Sung, Pingtung (TW); Wen-Pin Huang, Tainan (TW)

Correspondence Address: BIRCH STEWART KOLASCH & BIRCH, PO BOX 747, FALLS CHURCH, VA, 22040-0747, US

(73) Assignee: Advanced Semiconductor Engineering Inc.

(21) Appl. No.: 11/480,841

(22) Filed: Jul. 6, 2006

(30) Foreign Application Priority Data
Aug. 4, 2005 (TW) 94126622

(51) Int. Cl. H01L 23/34

(52) U.S. Cl. 257/723

(57) ABSTRACT

The package module comprising a first substrate, a first package, a second package and a molding compound. The first substrate has a first surface. The first package comprises a first chip and a liquid encapsulating compound. The first chip is disposed on the first substrate and electrically connected to the first substrate by a first gold wire. The liquid encapsulating compound encloses a second surface of the first chip and part of the first gold wire. A surface of the liquid encapsulating compound provides a platform. The molding compound encloses at least partial first surface of the first substrate, the first package and the second package.

This application claims the benefit of Taiwan application Serial No. 094126622, filed Aug. 4, 2005, the subject matter of which is incorporated herein by reference.

### BACKGROUND OF THE INVENTION

1. Field of the Invention

The invention relates in general to a package module, and more particularly to the package module having a stacking platform.

2. Description of the Related Art

With the development of chip package technology, the recent industry has implemented the thin package by stacking the chips in one package. Also, another approach to improve the integration is to stack the chip packages to form a multi chip module (MCM), so called as “package in package”. FIG. 1 is a diagrammatic sketch in a sectional view of a conventional module of package in package. The package module 100 comprises a substrate 10, a first package 20, a second package 30 and a molding compound 40. The first package 20 comprises the chips 21, 23 and the spacer 50. The chip 21 is attached to the substrate 10, and electrically connected to the substrate 10 by the gold wires 22. The chip 23 is disposed on the chip 21, and electrically connected to the chip 21 and the substrate 10 by the gold wires 24 and 25, respectively. The second package 30, disposed on the spacer 50, comprises a substrate 31, a chip 32 and a molding compound 34. The chip 32 is attached to the substrate 31 (such as by using epoxy), and electrically bonded to the substrate 31 by the gold wires 33. The chip 32 is also electrically connected to the substrate 10 by the gold wires 35. The molding compound 34 encloses the substrate 31, the chip 32 and the gold wires 33. Besides, the molding compound 40 is formed to enclose the surface 12 of the substrate 10, the first package substrate 20 and the second package 30. Several solder balls 11 are attached to the bottom surface of the substrate 10.

However, it is inevitable that some of chips in the conventional package module will be defective to some extent, particularly the chip bonded to the substrate with bared wires, so as to decrease the yield of package module and raise the production cost. As shown in FIG. 1, the top surface 51 of the spacer 50 is used for supporting the second package 30, but the second package 30 could not keep its balance on the small area of the top surface 51 while a light vibration or collision happens to the package module 100. If the second package 30 tilts and crash the gold wires 22, 24 and 25, the electrical test of the package module 100 fails. Moreover, it is difficult for the molding compound 40 to fully encapsulate every element in the package module 100 without bringing the air holes, due to the existence of the spacer 50 and the gold wires 22, 24, 25. The molding compound 40 with the air holes may burst when heated in the subsequent process, which is known as the “popcorn effect”.

### SUMMARY OF THE INVENTION

It is therefore an object of the present invention to provide a package module having a stacking platform. For steadily supporting the package in the module, a liquid encapsulating compound is used to be the stacking platform. Thus, the configurations and bonding positions of the gold wires in the module can be perfectly maintained.

The present invention achieves the objects by providing a package module comprising a first substrate, a first package, a second package and a molding compound. The first substrate has a first surface. The first package comprises a first chip and a liquid encapsulating compound. The first chip is disposed on the first substrate and electrically connected to the first substrate by a first gold wire. The liquid encapsulating compound encloses a second surface of the first chip and part of the first gold wire. A surface of the liquid encapsulating compound provides a platform, and the second package is disposed on the platform for package stacking. The molding compound encloses at least partial first surface of the first substrate, the first package and the second package.

The present invention achieves the objects by providing a method of fabricating a package module. First, a first substrate having a first surface is provided. A first chip is then disposed on the first substrate. The first chip is electrically connected to the first substrate by a first gold wire. Next, a liquid encapsulating compound is provided to enclose a second surface of the first chip and part of the first gold wire. The surface of the liquid encapsulating compound provides a platform. A second package is then disposed on the platform. A molding compound is provided to enclose at least partial first surface of the first substrate, the first package and the second package.

Other objects, features, and advantages of the present invention will become apparent from the following detailed description of the preferred but non-limiting embodiments. The following description is made with reference to the accompanying drawings.

### BRIEF DESCRIPTION OF THE DRAWINGS

FIG. 1 (prior art) is a diagrammatic sketch in a sectional view of a conventional module of package in package.

FIG. 2 is a diagrammatic sketch in a sectional view of a package module having a stacking platform according to the first embodiment of the invention.

FIG. 3A-FIG. 3G diagrammatically sketch a fabrication process of the package module according to the first embodiment of the invention.

FIG. 4 is a diagrammatic sketch in a sectional view of a package module having a stacking platform according to the second embodiment of the invention.

### DETAILED DESCRIPTION OF THE INVENTION

In the present invention, a package module having a stacking platform is disclosed. It is noted that the embodiments disclosed herein is used for illustrating the present invention, but not for limiting the scope of the present invention. Additionally, the drawings used for illustrating the embodiments and applications of the present invention only show the major characteristic parts in order to avoid obscuring the present invention. The drawings are diagrammatically show features of the present invention and their relation to other features and structures, and are not made to scale. Accordingly, the specification and the drawings are to be regard as an illustrative sense rather than a restrictive sense.

### First Embodiment

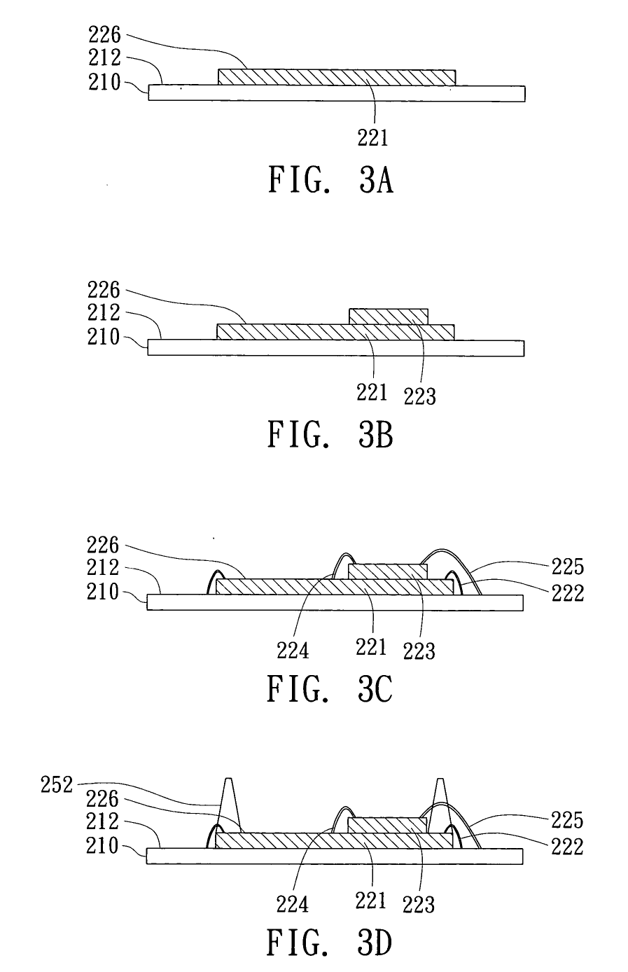

FIG. 2 is a diagrammatic sketch in a sectional view of a package module having a stacking platform according to the first embodiment of the invention. The package module 200 comprises a substrate 210, a first package 220, a second package 230 and a molding compound 240. Any of various substrate types may be used. The first package 220 comprises the chips 221, 223 and the liquid encapsulating compound 250. The chip 221 is attached to the substrate 210 (such as by using epoxy), and wire bonded to the substrate 210 by the gold wires 222 to establish electrical connection. The chip 223 is disposed on the chip 221, and electrically connected to the chip 221 and the substrate 210 by the gold wires 224 and 225, respectively.

The second package 230 is disposed on the platform 251 provided by the upper surface of the liquid encapsulating compound 250. The second package 230 comprises a substrate 231, a chip 232 and a molding compound 234. The chip 232 is attached to the substrate 231 (such as by using epoxy), and wire bonded to the substrate 231 by the gold wires 233 to establish electrical connection. The chip 232 is electrically connected to the substrate 210 by the gold wires 235. The molding compound 234 encloses the substrate 231, the chip 232 and the gold wires 233. Besides, the molding compound 240 is formed to enclose the surface 212 of the substrate 210, the first package substrate 220 and the second package 230. Also, several solder balls 211 are attached to the bonding pads (not shown) on the bottom surface of the substrate 210.

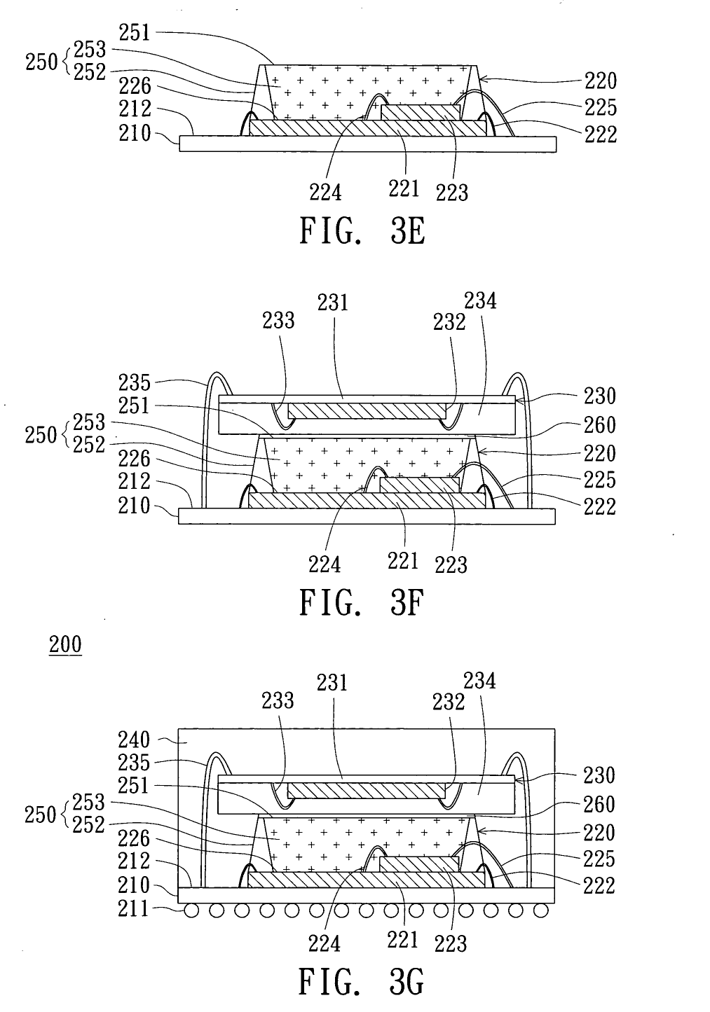

FIG. 3A-FIG. 3G diagrammatically sketch a fabrication process of the package module according to the first embodiment of the invention. First, a substrate 210 having a surface 212 is provided, and a chip 221 is disposed on (attached to) the surface 212 of the substrate 210, as shown in FIG. 3A. Next, a chip 223 is disposed on the surface 216 of the chip 221, as shown in FIG. 3B. Then, the wire-bonding step proceeds. The gold wires 222 is provided for wire bonding the chip 221 to the substrate 210, the gold wires 224 is provided for wire bonding the chips 221 and 223, and the gold wires 225 is provided for wire bonding the chip 223 and the substrate 210, as shown in FIG. 3C. Next, a viscous molding compound (having relatively high resistance to flow) is provided to form a dam block 252 on the surface 226 of the chip 221, as shown in FIG. 3D. Preferably, the dam block 252 is disposed on the periphery of the surface 226 of the chip 221 for creating a receiving space at the central portion of the surface 226.

Afterward, the receiving space at the central portion of the surface 226 created by the dam block 252 is filled with an encapsulation compound 253 having lower resistance to flow (such as silver epoxy), as shown in FIG. 3D. The liquid encapsulating compound 250, consisting of the dam block 252 and the encapsulation compound 253, encloses the gold wires 224, the surface 226 of the chip 221, the chip 223 and portions of the gold wires 222 and 225. Then, the encapsulating structure is heated in the oven. After the liquid encapsulating compound 250 is cured, the surface of the liquid encapsulating compound 250 is planarized to form a platform 251 (for supporting a second package 230 later).

Next, a second package 230 is attached to the platform 251 by silver epoxy 260, as shown in FIG. 3F. The second package 230 comprises a substrate 231, a chip 232 and a molding compound 234. The chip 232 is attached to the substrate 231, and wire bonded to the substrate 231 by the gold wires 233. The molding compound 234 encloses the chip 232, the gold wires 233 and the substrate 231. The second package 230 is electrically connected to the substrate 210 by the gold wires 235. Then, the molding compound 240 is provided to enclose the (partial or entire) surface 212 of the substrate 210, the first package substrate 220 and the second package 230, as shown in FIG. 3G. The molding compound 240 shown by way of example in FIG. 3G has enclosed the entire surface 212 of the substrate 210. Afterward, several solder balls 211 are attached to the bonding pads (not shown) on the bottom surface of the substrate 210, to complete the fabrication process of the package module 200.

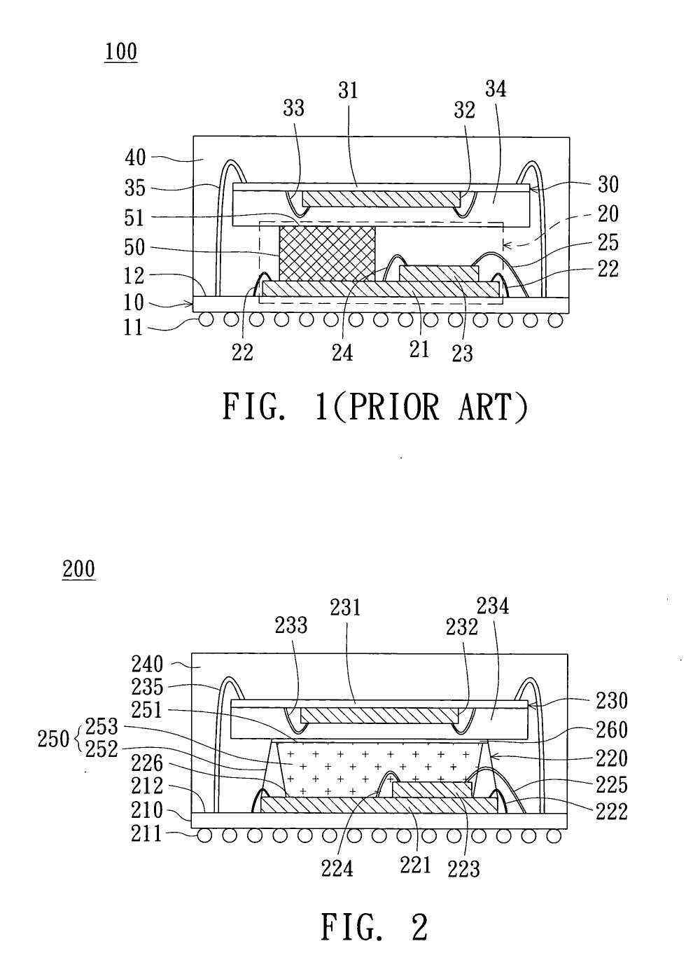

In the package module 200 of the first embodiment, the liquid encapsulating compound 250 encloses the gold wires 224, 222, 225 and the chips 221, 223, and the surface of the liquid encapsulating compound 250 provides the platform 251 for disposing the second package 230. Compared to the conventional spacer 50 of FIG. 1, the liquid encapsulating compound 250 fully protects the chips 221, 223 and the gold wires 224, 222, 225. The gold wires 224, 222, 225 remain the original wire-bonding configurations, and short circuit won't happen.

Besides, the platform 251 provided by the surface of the liquid encapsulating compound 250 is almost has the same top area as the chip 221. Compared to the conventional spacer 50, having a small top area and located near the left side of the chip 23, the platform 251 provides a larger supporting surface for disposing the second package 230. Also, the platform 251 touches the most bottom area of the second package 230, so that the second package 230 can be disposed on the platform 251 steadily. The conventional tilting problem of the second package 30 can be solved.

Moreover, the liquid encapsulating compound 25 having lower resistance to flow is adopted in the embodiment for protecting the chips 221 and 223. Compared to the conventional molding compound (reference number 40 in FIG. 1) formed by molding, the possibility of the undesired air hole formation in the liquid encapsulating compound 25 is greatly decreased. Accordingly, the yield of the package fabricated according to the embodiment is increased.

### Second Embodiment

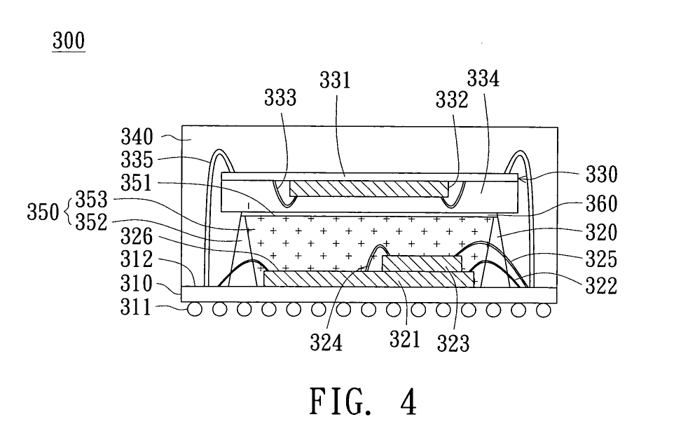

FIG. 4 is a diagrammatic sketch in a sectional view of a package module having a stacking platform according to the second embodiment of the invention. The differences between the package module 300 of the first embodiment and the package module 200 of the second embodiment is that the liquid encapsulating compound 350 encloses not only the entire surface 326 of the chip 321 but also part of the surface 312 of the substrate 310. In the second embodiment, the dam block 352 can be formed at the periphery of the surface 312 of the substrate 310 and spaced from the chip 321 for an interval. Then, the receiving space created by the dam block 352 is filled with an encapsulation compound 353 having lower resistance to flow. Thus, the liquid encapsulating compound 350, consisting of the dam block 352 and the encapsulation compound 353, encloses the surface 326 of the chip 321, and the partial surface 312 of the chip 310. The structural configuration and fabrication of the other elements in FIG. 4 are the same as that in FIG. 2, and not described again.

The package module 300 also possesses the advantages as the package module 200, such as fully protect the gold wires in the first package 320, providing a larger supporting platform for the second package 330, and almost no air hole formed in the liquid encapsulating compound 350. Since the area of the platform 351 of the liquid encapsulating compound 350 is larger than the area of the platform 251 of the liquid encapsulating compound 250, the second package 330 disposed on the platform 351 is steadier than the second package 230 disposed on the platform 251.

According to the aforementioned description, the package module having a stacking platform can fully protect the chips and the gold wires. Besides, the liquid encapsulating compound (250/350) enclosing the first package (220/320) provides a large supporting area for disposing the second package (230/330) steadily. Also, the platform of the invention can be fabricated using a simple process, which is cost saving. The conventional problem of gold wire crashed by the tilted package can be solved since the gold wires of the invention are fully protected by the liquid encapsulating compound. Thus, the yield of the package module of the invention is increased, and the electrical test of each package in the package module of the invention shows a satisfactory result.

While the invention has been described by way of example and in terms of the preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package module, comprising:
a first substrate, having a first surface;
a first package, comprising:
a first chip, disposed on the first substrate and electrically connected to the first substrate by a first gold wire;
a liquid encapsulating compound, enclosing a second surface of the first chip and part of the first gold wire, a surface of the liquid encapsulating compound providing a platform;
a second package, disposed on the platform; and
a molding compound, enclosing at least partial first surface of the first substrate, the first package and the second package.

2. The package module according to claim 1, wherein the liquid encapsulating compound encloses entire the first chip, and partial first surface of the first substrate.

3. The package module electrochromic device according to claim 1, wherein the second package comprises a second chip, a second substrate and a second gold wire; the second chip is electrically connected to the second substrate by a second gold wire.

4. The package module according to claim 3, further comprising a third chip disposed on the second surface of the first chip, and the liquid encapsulating compound enclosing the third chip.

5. The package module according to claim 4, wherein the third chip is electrically connected to the first chip by a third gold wire, and the liquid encapsulating compound encloses the third gold wire.

6. The package module according to claim 5, wherein the third chip is electrically connected to the first substrate by a fourth gold wire, and the liquid encapsulating compound encloses the fourth gold wire.

7. The package module according to claim 1, wherein the second package is disposed on the platform using a silver epoxy.

8. The package module according to claim 1, wherein a plurality of solder balls are formed on a bottom surface of the first substrate.

9. A method of fabricating a package module, comprising:
providing a first substrate having a first surface;
disposing a first chip on the first substrate;
electrically connecting the first chip to the first substrate by a first gold wire;
providing a liquid encapsulating compound to enclose a second surface of the first chip and part of the first gold wire, and a surface of the liquid encapsulating compound providing a platform;
disposing a second package on the platform; and
providing a molding compound to enclose at least partial first surface of the first substrate, the first package and the second package.

10. The method according to claim 9, wherein the liquid encapsulating compound encloses the second surface of the first chip, partial first gold wire, and partial first surface of the substrate.

11. The method according to claim 9, wherein the second package comprises a second chip, a second substrate and a second gold wire; the second chip is electrically connected to the second substrate by a second gold wire when the second package is disposed on the platform.

12. The method according to claim 11, wherein after disposing the first chip on the first substrate, the method further comprises:
disposing a third chip on the second surface of the first chip;
in the step of proving the liquid encapsulating compound to enclose a second surface of the first chip and part of the first gold wire, the liquid encapsulating compound further encloses the third chip.

13. The method according to claim 12, wherein after disposing a third chip on the second surface of the first chip, the method further comprises:
electrically connecting the third chip to the first chip by a third gold wire, and electrically connecting the third chip to the first substrate;
wherein the liquid encapsulating compound encloses the third gold wire and partial the fourth gold wire.

14. The method according to claim 9, wherein in the step of disposing the second package on the platform, a silver epoxy is used for attaching the second package on the platform.
